(19) United States
(12) Patent Application Publication
(10) Pub. No.: US 2026/0206427 A1
(43) Pub. Date: Jul. 16, 2026

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventor: CHUNGI YOU, Yongin-si (KR)

(73) Assignee: Samsung Display Co., LTD., Yongin-si (KR)

(21) Appl. No.: 19/404,877

(22) Filed: Dec. 1, 2025

(30) Foreign Application Priority Data
Jan. 13, 2025 (KR) 10-2025-0004782

(51) Int. Cl. H10K 59/123; H10K 59/12; H10K 59/124

(52) U.S. Cl. CPC H10K 59/123; H10K 59/1201; H10K 59/124

(57) ABSTRACT

A display device includes a transistor disposed on a substrate, a first insulating layer disposed on the transistor and including a first hole having a first diameter of about 1.5μm to about 2.0μm in a plan view, a second insulating layer covering an upper surface of the first insulating layer and an inner surface of the first hole, and including a second hole having a second diameter of 0.8μm or less in a plan view, a conductive pattern disposed in the second hole of the second insulating layer and electrically connected to the transistor, and a light-emitting diode disposed on the conductive pattern.

### CROSS-REFERENCE TO RELATED APPLICATION(S)

This application claims priority to and benefits of Korean Patent Application No. 10-2025-0004782 under 35 U.S.C. § 119, filed on January 13, 2025, the entire contents of which are incorporated herein by reference.

### BACKGROUND

### Technical Field

The disclosure relates to a display device, a method of manufacturing the display device, and an electronic device including the display device. More specifically, the disclosure relates to the display device that provides visual information, the method of manufacturing the display device, and the electronic device including the display device.

### Description of the Related Art

As various portable electronic devices such as mobile communication terminals and notebook computers are developed, a demand for display devices that may be applied to them is increasing. Widely known display devices include liquid crystal display devices, plasma display panels, and organic light emitting diode display devices. Among these display devices, research on micro OLEDs, which have various advantages such as advancement in mass production technology, ease of driving means, low power consumption, high definition, and large screen implementation, is continuing.

Micro OLEDs have an advantage of being able to have high definition display devices compared to existing OLEDs, but they have a challenge of requiring high integration of transistors, etc. To solve this challenge, efforts are being made to reduce the diameter of holes, etc. when forming holes, etc.

### SUMMARY

One purpose of the disclosure is to provide a display device being implemented with high pixels.

Another purpose of the disclosure is to provide a method of manufacturing the display device.

Still another purpose of the disclosure is to provide an electronic device including the display device.

A display device according to an embodiment includes a transistor disposed on a substrate, a first insulating layer disposed on the transistor and including a first hole having a first diameter of about 1.5μm to about 2.0μm in a plan view, a second insulating layer covering an upper surface of the first insulating layer and an inner surface of the first hole, and including a second hole having a second diameter of 0.8μm or less in a plan view, a conductive pattern disposed in the second hole of the second insulating layer and electrically connected to the transistor, and a light-emitting diode disposed on the conductive pattern.

In an embodiment, a second thickness of the second insulating layer may be greater than a first thickness of the first insulating layer.

In an embodiment, the second thickness of the second insulating layer may be in a range of about 500nm to about 600nm.

In an embodiment, each of the first hole and the second hole may have a trapezoidal shape in a cross-sectional view.

In an embodiment, an acute angle between an inner surface of the second hole and an upper surface of the substrate may be about 80 degrees or more.

In an embodiment, each of the first insulating layer and the second insulating layer may include an inorganic material.

In an embodiment, the second hole may expose an upper surface of a source/drain electrode of the transistor.

In an embodiment, the second hole may penetrate the first insulating layer and the second insulating layer in a thickness direction.

In an embodiment, the conductive pattern may extend in a thickness direction along the second hole.

In an embodiment, the conductive pattern may be electrically connected to a pixel electrode of the light-emitting diode.

A method of manufacturing a display device according to another embodiment includes forming a transistor on a substrate, depositing a first insulating layer on the transistor, forming a first hole including a first diameter of about 1.5μm to about 2.0μm in a plan view in the first insulating layer, depositing a second insulating layer on an upper surface of the first insulating layer and an inner surface of the first hole, the second insulating layer defining a second hole including a second diameter of about 0.8μm or less in a plan view, etching the second insulating layer to expose an upper surface of a source/drain electrode of the transistor, forming a conductive pattern in the second hole, and forming a light-emitting diode on the conductive pattern.

In an embodiment, the method may further include applying a photoresist on the second insulating layer after depositing the second insulating layer.

In an embodiment, in the applying of the photoresist, the photoresist may be spaced apart from the first hole in a plan view.

In an embodiment, in the depositing of the second insulating layer, a thickness of the second insulating layer may be formed thicker than a thickness of the first insulating layer.

In an embodiment, in the forming of the second hole, an acute angle between an inner surface of the second hole and an upper surface of the substrate may be about 80 degrees or more.

In an embodiment, the etching of the second insulating layer may include an anisotropic etching process.

An electronic device according to an embodiment includes a display device and a processor that drives the display device, and wherein the display device includes a transistor disposed on a substrate, a first insulating layer disposed on the transistor and defining a first hole including a first diameter of about 1.5μm to about 2.0μm in a plan view, a second insulating layer covering an upper surface of the first insulating layer and an inner surface of the first hole, and defining a second hole including a second diameter of 0.8μm or less in a plan view, a conductive pattern disposed in the second hole of the second insulating layer and electrically connected to the transistor, and a light-emitting diode disposed on the conductive pattern.

In an embodiment, a first thickness of the first insulating layer may be less than a second thickness of the second insulating layer.

In an embodiment, the second hole may have a trapezoidal shape in a cross-sectional view, and an acute angle between an inner surface of the second hole and an upper surface of the substrate may be about 80 degrees or more.

In an embodiment, the second hole may expose an upper surface of a source/drain electrode of the transistor.

A display device according to an embodiment may include a transistor disposed on a substrate, a first insulating layer disposed on the transistor and defining a first hole including a first diameter of about 1.5μm to about 2.0μm in a plan view, a second insulating layer covering an upper surface of the first insulating layer and an inner surface of the first hole, and defining a second hole including a second diameter of 0.8μm or less in a plan view, a conductive pattern disposed in the second hole of the second insulating layer and electrically connected to the transistor, and a light-emitting diode disposed on the conductive pattern.

Accordingly, by arranging a second hole having a second diameter inside the first hole having the first diameter, an area of the hole in which the conductive pattern is disposed may be reduced. As an area of the hole is reduced, components of the display device such as the transistor may be disposed relatively in a high-density manner.

In addition, in a method of manufacturing the display device, even when using exposure equipment that emits light having a width of about 1.5 μm to about 2.0 μm, a diameter of the hole may be reduced to about 0.8 μm or less. Accordingly, the second hole having the second diameter may be formed even without replacing the exposure equipment, etc. with one having a smaller width.

### BRIEF DESCRIPTION OF THE DRAWINGS

The accompanying drawings, which are included to provide a further understanding of the invention and are incorporated in and constitute a part of this specification, illustrate embodiments of the invention together with the description.

FIG. 1 is a schematic perspective view showing a display device according to an embodiment of the disclosure.

FIG. 2 is a schematic cross-sectional view showing an embodiment of the display device of FIG. 1.

FIG. 3 is a schematic cross-sectional view showing an embodiment of the display panel of FIG. 2.

FIG. 4 is an enlarged schematic cross-sectional view of area A of FIG. 3.

FIGS. 5 to 15 are schematic cross-sectional views showing embodiments of a method of manufacturing the display panel of FIG. 3.

FIG. 16 is a block diagram showing an electronic device according to an embodiment of the disclosure.

FIG. 17 is schematic diagrams showing various embodiments of the electronic device of FIG. 16.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element (or a layer) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the X, Y, and Z – axes, and may be interpreted in a broader sense. For example, the D1-axis, the D2-axis, and the D3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element’s relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein are interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

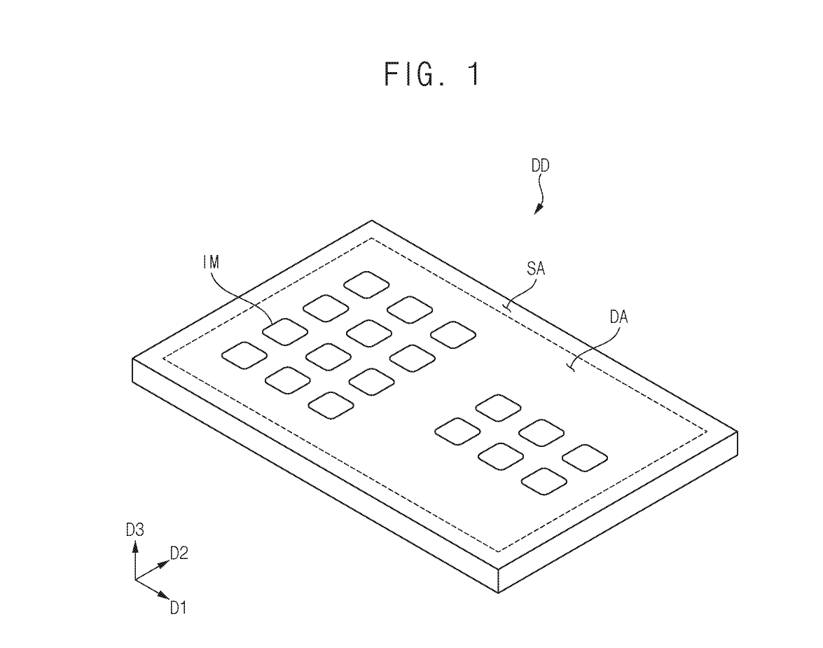

FIG. 1 is a schematic perspective view showing a display device according to an embodiment of the disclosure.

Referring to FIG. 1, the display device DD may include a display area DA and a peripheral area SA. The display area DA may be at least partially surrounded by the peripheral area SA.

The display area DA may be an area capable of generating light. The display area DA may be an area capable of adjusting a transmittance of light provided from an external light source to display an image. The peripheral area SA may be an area that does not display an image. However, embodiments are not limited thereto. At least a portion of the peripheral area SA may also display an image.

The display area DA may display a plurality of images IM. Through the plurality of images IM, users may receive information from the display device DD.

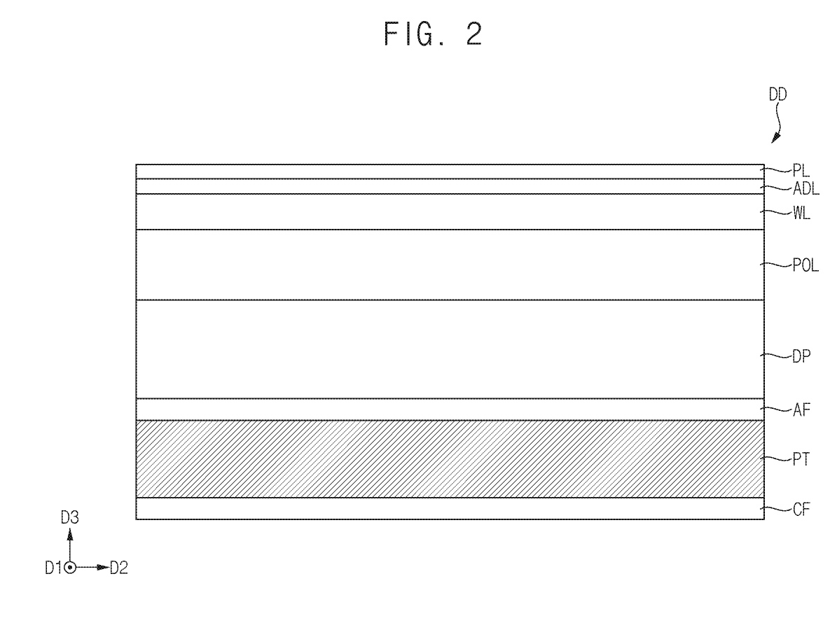

FIG. 2 is a schematic cross-sectional view showing an embodiment of the display device of FIG. 1.

Referring to FIGS. 1 and 2, the display device DD may include a cover film CF, a plate PT, an adhesive film AF, a display panel DP, a polymer layer POL, a window layer WL, an adhesive layer ADL, and a protective film PL.

The cover film CF may be disposed on a rear surface of the display device DD. The cover film CF may cushion an impact received from the outside of the display device DD. The cover film CF may include at least one of sponge, foam, thermoplastic polyurethane, and polydimethylacrylamide. These may be used alone or in combination with each other. In another example, the cover film CF may include a light-blocking material. Accordingly, the cover film CF may absorb light incident from a rear surface of the display device DD.

The plate PT may be disposed on the cover film CF. The plate PT may prevent the display panel DP from bending due to an external force. For example, the plate PT may maintain the display panel DP in a relatively flat state even when an external force is applied to the display device DD. The plate PT may include a material having rigidity. The plate PT may include a material having semi-rigidity. For example, the plate PT may include at least one of iron, chromium, carbon, nickel, silicon, manganese, and molybdenum. These may be used alone or in combination with each other. However, embodiments are not limited thereto.

The adhesive film AF may be disposed on the plate PT. The adhesive film AF may attach the plate PT and the display panel DP. For example, the adhesive film AF may include at least one of a pressure-sensitive adhesive (PSA), an optical clear adhesive (OCA), and an optical clear resin (OCR). These may be used alone or in combination with each other. However, embodiments are not limited thereto.

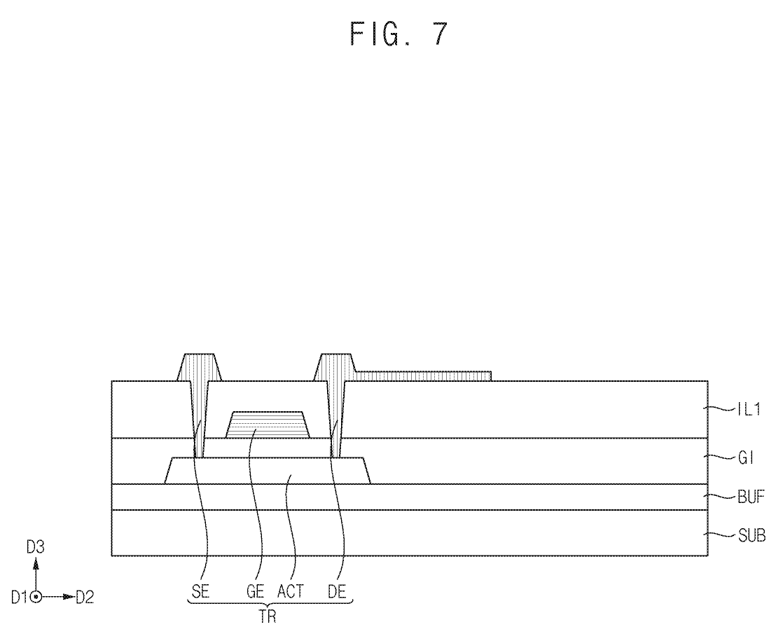

The display panel DP may be disposed on the adhesive film AF. The display panel DP may generate light in response to an input signal. Accordingly, the display panel DP may provide a visual image to a user of the display device DD. Descriptions regarding the display panel DP will be described later with reference to FIG. 7.

The polymer layer POL may be disposed on the display panel DP. The polymer layer POL may attach the display panel DP and the window layer WL. The polymer layer POL may support the window layer WL to prevent sagging. The polymer layer POL may protect the display panel DP from external impacts. The polymer layer POL may have a single-layer structure or a multi-layer structure.

The window layer WL may be disposed on the polymer layer POL. The window layer WL may cover a front surface of the display device DD. The window layer WL may protect the display panel DP. The window layer WL may include a substantially transparent material. For example, the window layer WL may be made of glass or plastic. However, embodiments are not limited thereto.

The adhesive layer ADL may be disposed on the window layer WL. The adhesive layer ADL may attach the window layer WL and the protective film PL. The adhesive layer ADL may include a transparent material. For example, the adhesive layer ADL may include at least one of a pressure-sensitive adhesive (PSA), an optical clear adhesive (OCA), and an optical clear resin (OCR). These may be used alone or in combination with each other. However, embodiments are not limited thereto.

The protective film PL may be disposed on the adhesive layer ADL. The protective film PL may protect the window layer WL from external impacts. The protective film PL may protect the window layer WL from scratches. For example, the protective film PL may include a base layer or a hard coating layer. However, embodiments are not limited thereto. The protective film PL may further include a low refractive index layer and/or a fingerprint-resistant layer.

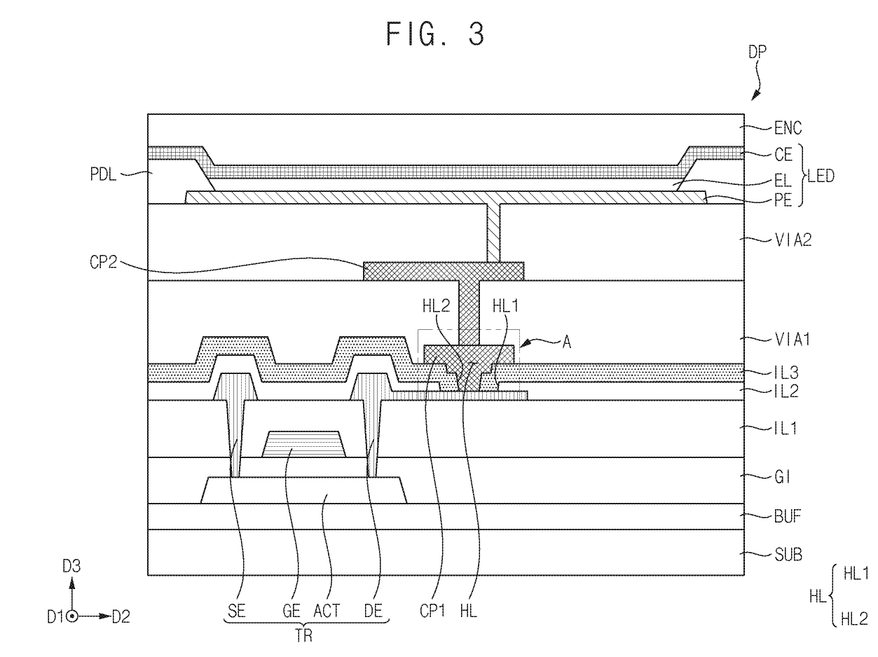

FIG. 3 is a schematic cross-sectional view showing an embodiment of the display panel of FIG. 2.

Referring to FIGS. 2 and 3, the display panel DP may include a substrate SUB, a buffer layer BUF, a transistor TR, a gate insulating layer GI, first, second, and third interlayer insulating layers IL1, IL2, and IL3, first and second conductive patterns CP1 and CP2, a light-emitting diode LED, a pixel defining layer PDL, and an encapsulation layer ENC.

The transistor TR may include an active layer ACT, a gate electrode GE, a source electrode SE, and a drain electrode DE. The light-emitting diode LED may include a pixel electrode PE, an emission layer EL, and a common electrode CE.

The substrate SUB may include a glass substrate, a metal substrate, or a plastic substrate. For example, the plastic substrate of the substrate SUB may include polyimide. However, embodiments are not limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating from the substrate SUB to an upper portion of the substrate SUB. The buffer layer BUF may include an inorganic insulating material.

The above active layer ACT may be disposed on the buffer layer BUF. The active layer ACT may include an oxide semiconductor, a silicon semiconductor, an organic semiconductor, etc. For example, the oxide semiconductor may include at least one oxide from among indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, etc. The active layer ACT may include a source region, a drain region, and a channel region positioned between the source region and the drain region.

The gate insulating layer GI may be disposed on the buffer layer BUF. For example, the gate insulating layer GI may cover the active layer ACT on the buffer layer BUF. The gate insulating layer GI may include an inorganic insulating material. In an embodiment, the gate insulating layer GI may be disposed over the entire display area DA and the peripheral area SA. In an embodiment, the gate insulating layer GI may be disposed only under the gate electrode GE.

The gate electrode GE may be disposed on the gate insulating layer GI. The gate electrode GE may overlap at least a portion of the channel region of the active layer ACT. The gate electrode GE may include a conductive material such as a metal, an alloy, a conductive metal nitride, a conductive metal oxide, or a transparent conductive material. Examples of the conductive material that may be used for the gate electrode GE include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc. oxide (IZO), etc. These may be used alone or in combination with each other. In another example, the gate electrode GE may have a single-layer structure or a multi-layer structure including a plurality of conductive layers.

The first interlayer insulating layer IL1 may be disposed on the gate insulating layer GI. For example, the first interlayer insulating layer IL1 may be disposed on the gate insulating layer GI and may cover the gate electrode GE. The first interlayer insulating layer IL1 may be disposed over the entire display area DA and the peripheral area SA. The first interlayer insulating layer IL1 may include an inorganic insulating material.

The source electrode SE and the drain electrode DE may be disposed on the first interlayer insulating layer IL1. Each of the source electrode SE and the drain electrode DE may be connected to the active layer ACT. For example, the source electrode SE may contact (e.g., directly contact) the source region of the active layer ACT, and the drain electrode DE may contact (e.g., directly contact) the drain region of the active layer ACT. Each of the source electrode SE and the drain electrode DE may include a conductive material.

The second interlayer insulating layer IL2 may be disposed on the source electrode SE and the drain electrode DE. For example, the second interlayer insulating layer IL2 may be disposed on the first interlayer insulating layer IL1 and may cover the source electrode SE and the drain electrode DE. The second interlayer insulating layer IL2 and the first interlayer insulating layer IL1 may include substantially a same material.

In an embodiment, a first hole HL1 may be defined (or formed) in the second interlayer insulating layer IL2. As the first hole HL1 is defined (or formed), a signal generated in the transistor TR may be transmitted to the light-emitting diode LED through a metal pattern, etc. For example, the first hole HL1 may penetrate the second interlayer insulating layer IL2 in the third direction D3. The first hole HL1 may expose at least a portion of an upper surface of the drain electrode DE of the transistor TR.

The third interlayer insulating layer IL3 may be disposed on the second interlayer insulating layer IL2. The third interlayer insulating layer IL3 may be disposed on the second interlayer insulating layer IL2 and may cover an inner surface of the first hole HL1 defined (or formed) by the second interlayer insulating layer IL2. For example, the third interlayer insulating layer IL3 may extend in a thickness direction of the display panel DP (e.g., the third direction D3) along an inner surface of the first hole HL1.

In an embodiment, a second hole HL2 may be defined (or formed) in the third interlayer insulating layer IL3. The first conductive pattern CP1 may be disposed inside the second hole HL2. For example, the second hole HL2 may be a passage for transmitting a signal of the transistor TR through the first conductive pattern CP1.

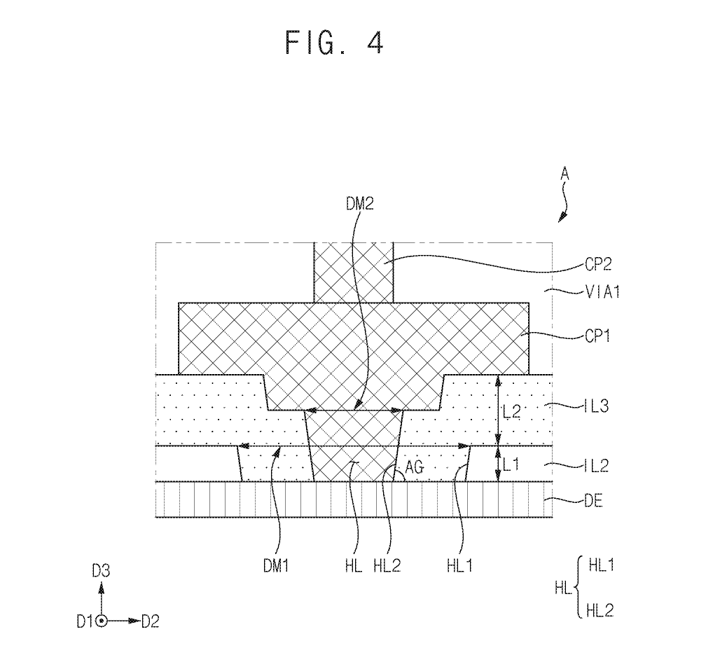

In an embodiment, the first hole HL1 and the second hole HL2 may overlap in a plan view. For example, the first hole HL1 and the second hole HL2 may overlap in a plan view to define one hole HL. Since the first hole HL1 is defined (or formed) in the second interlayer insulating layer IL2 and the second hole HL2 is defined (or formed) in the third interlayer insulating layer IL3, the second hole HL2 may be defined (or formed) inside the first hole HL1. Accordingly, a second diameter (e.g., the second diameter DM2 of FIG. 4) of the second hole HL2 may be less than a first diameter (e.g., the first diameter DM1 of FIG. 4) of the first hole HL1.

The first conductive pattern CP1 may be disposed in the second hole HL2 defined (or formed) by the third interlayer insulating layer IL3. For example, the first conductive pattern CP1 may be disposed on the third interlayer insulating layer IL3 and may extend into an interior (or inside) of the second hole HL2. Accordingly, the first conductive pattern CP1 may fill an interior (or inside) of the second hole HL2.

For example, the first conductive pattern CP1 may include a metal, an alloy, a metal nitride, a conductive metal oxide, a transparent conductive material, etc. These may be used alone or in combination. However, embodiments are not limited thereto.

In an embodiment, the first conductive pattern CP1 may be electrically connected to the drain electrode DE of the transistor TR. Accordingly, an electric signal transmitted from the transistor TR may be applied to the light-emitting diode LED through the first conductive pattern CP1.

The first via layer VIA1 may be disposed on the third interlayer insulating layer IL3. For example, the first via layer VIA1 may be disposed on the third interlayer insulating layer IL3 and may cover the first conductive pattern CP1. The first via layer VIA1 may include an organic insulating material. In an embodiment, the first via layer VIA1 may be formed only on the display area DA and a portion of the peripheral area SA adjacent to the display area DA.

The second conductive pattern CP2 may be disposed on the first via layer VIA1. The second conductive pattern CP2 may transmit a signal transmitted from the transistor TR to the light-emitting diode LED. The second conductive pattern CP2 and the first conductive pattern CP1 may include substantially a same material.

The second via layer VIA2 may be disposed on the first via layer VIA1. For example, the second via layer VIA2 may be disposed on the first via layer VIA1 and may cover the second conductive pattern CP2. The second via layer VIA2 and the first via layer VIA1 may include substantially a same material.

The pixel electrode PE may be disposed on the second via layer VIA2. The pixel electrode PE may include a conductive material. The pixel electrode PE may be connected to the drain electrode DE through the first and second conductive patterns CP1 and CP2. Accordingly, the pixel electrode PE may be electrically connected to the transistor TR.

The pixel definition layer PDL may be disposed on the pixel electrode PE. For example, the pixel defining layer PDL may expose at least a portion of the pixel electrode PE. The pixel defining layer PDL may include an inorganic insulating material or an organic insulating material.

The light-emitting layer EL may be disposed on the pixel electrode PE. In an embodiment, the light-emitting layer EL may be disposed within an opening defined (or formed) by the pixel defining layer PDL. For example, the light-emitting layer EL may be surrounded by the pixel defining layer PDL. In an embodiment, the light-emitting layer EL may also be disposed on the pixel defining layer PDL. The light-emitting layer EL may include at least one of an organic light-emitting material and/or a quantum dot. However, the embodiment is not limited thereto.

The common electrode CE may be disposed on the light-emitting layer EL. The common electrode CE may also be disposed on the pixel defining layer PDL. For example, the common electrode CE may be disposed continuously on the light-emitting layer EL and the pixel defining layer PDL. The common electrode CE may include a conductive material. The light-emitting layer EL may emit light based on a voltage difference between the pixel electrode PE and the common electrode CE.

The encapsulating layer ENC may be disposed on the common electrode CE. The encapsulating layer ENC may include at least one inorganic encapsulating layer and at least one organic encapsulating layer. In an embodiment, the inorganic encapsulating layer and the organic encapsulating layer may be alternately disposed. For example, the organic encapsulating layer may include a polymer cured material such as polyacrylate, epoxy resin, silicone resin, etc. For example, the inorganic encapsulating layer may include silicon oxide, silicon nitride, silicon carbide, aluminum oxide, tantalum oxide, hafnium oxide, zirconium oxide, titanium oxide, etc.

FIG. 4 is an enlarged schematic cross-sectional view of area A of FIG. 3.

Referring to FIGS. 3 and 4, the second interlayer insulating layer IL2 may have a first thickness L1 and may define a first hole HL1 having the first diameter DM1. The third interlayer insulating layer IL3 may have a second thickness L2 and may define a second hole HL2 having the second diameter DM2.

In an embodiment, the first diameter DM1 of the first hole HL1 may be about 1.5μm to about 2μm. For example, the first diameter DM1 of the first hole HL1 may be about 1.5μm to about 1.8μm. The first diameter DM1 of the first hole HL1 may be defined (or determined) based on a beam width of light used to form the first hole HL1.

In an embodiment, the second diameter DM2 of the second hole HL2 may be 0.8μm or less. For example, the second diameter DM2 of the second hole HL2 may be 0.5μm or less. For example, since the second hole HL2 is defined (or formed) inside the first hole HL1, the second diameter DM2 of the second hole HL2 may be less than the first diameter DM1 of the first hole HL1. Since the second diameter DM2 satisfies the above-described range, an area occupied by the first conductive pattern CP1 on the transistor TR in a plan view may be reduced, so that a display device including a highly integrated transistor (e.g., the display device DD of FIG. 1) may be manufactured.

In an embodiment, the second thickness L2 of the third interlayer insulating layer IL3 may be greater than the first thickness L1 of the first interlayer insulating layer IL1. Since the second thickness L2 of the third interlayer insulating layer IL3 is greater than the first thickness L1 of the second interlayer insulating layer IL2, a size of the second hole HL2 may be reduced. For example, the second thickness L2 may be about 500nm or more and about 600nm or less. For example, the second thickness L2 may be about 500nm or more and about 550nm or less. However, embodiments are not limited thereto.

In an embodiment, an inner wall of the second hole HL2 and the substrate (e.g., the substrate SUB of FIG. 3) may have a certain angle AG. An acute angle among the angle AG may be about 80 degrees or more. For example, the acute angle among the angle AG may be about 80 degrees or more. Since the angle AG satisfies the above-described range, the second hole HL2 may penetrate the third interlayer insulating layer IL3 substantially perpendicularly. Since the second hole HL2 penetrates the third interlayer insulating layer IL3 substantially perpendicularly, although the second diameter DM2 of the second hole HL2 is small, the second hole HL2 may penetrate the third interlayer insulating layer IL3 in a thickness direction.

In an embodiment, each of the first hole HL1 and the second hole HL2 may have a trapezoidal shape in a cross-sectional view. For example, each of the first hole HL1 and the second hole HL2 may have a trapezoidal shape in which the diameter decreases as it extends in a direction opposite to the third direction D3. However, embodiments are not limited thereto.

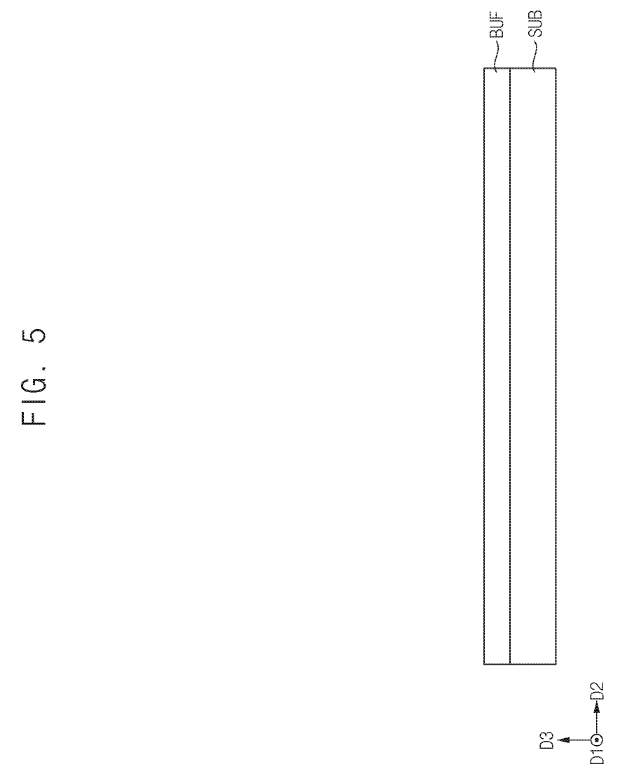

FIGS. 5 to 15 are schematic cross-sectional views showing embodiments of a method of manufacturing the display panel of FIG. 3.

Referring to FIG. 5, the buffer layer BUF may be formed on the substrate SUB. The buffer layer BUF may be formed in the display area (e.g., the display area DA of FIG. 1) and the peripheral area (e.g., the peripheral area SA of FIG. 1). The buffer layer BUF may include an inorganic material. Another layer (e.g., a light-blocking layer) may be further formed between the substrate SUB and the buffer layer BUF.

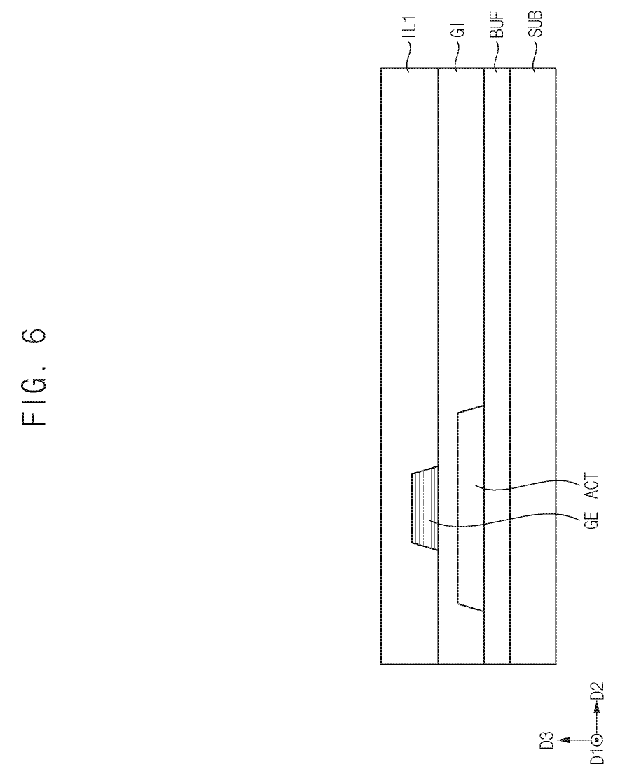

Referring further to FIGS. 6 and 7, the active layer ACT, the gate insulating layer GI, the gate electrode GE, the first interlayer insulating layer IL1, the source electrode SE, and the drain electrode DE may be sequentially formed on the buffer layer BUF. For example, the transistor TR may be formed on the buffer layer BUF.

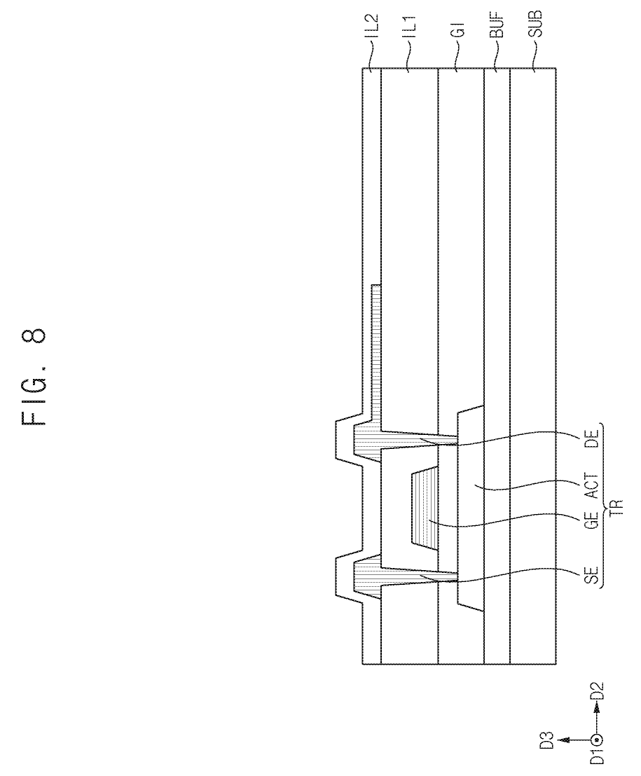

Referring further to FIG. 8, the second interlayer insulating layer IL2 may be formed on the first interlayer insulating layer IL1. The second interlayer insulating layer IL2 may be formed along the profiles (or upper surfaces) of the first interlayer insulating layer IL1, the source electrode SE, and the drain electrode DE. Accordingly, the second interlayer insulating layer IL2 may include bends along the third direction D3 in a cross-sectional view.

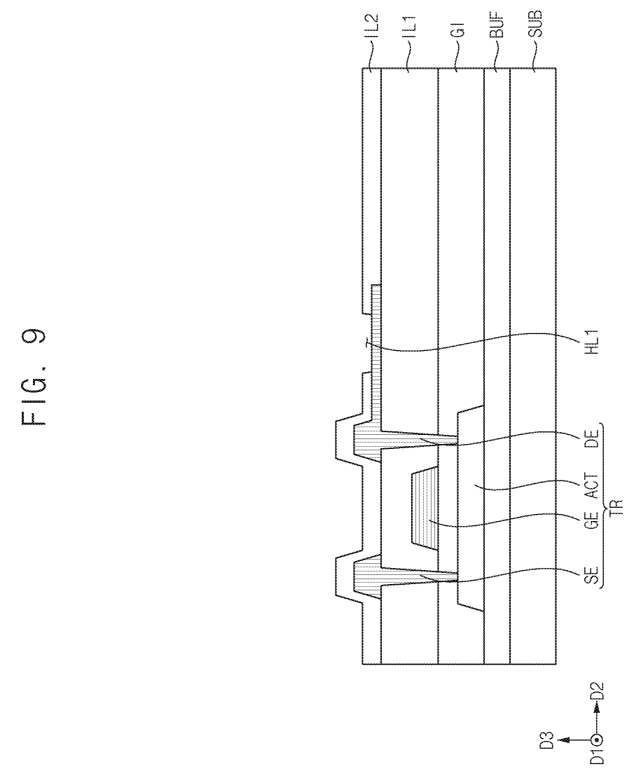

Referring further to FIGS. 4 and 9, a portion of the second interlayer insulating layer IL2 may be removed. The second interlayer insulating layer IL2 may be removed through processes such as exposure, development, and etching. By etching and removing the second interlayer insulating layer IL2, the first hole HL1 may be formed. The first hole HL1 may be formed to overlap the drain electrode DE of the transistor TR in a plan view. Accordingly, the first hole HL1 may expose at least a portion of an upper surface of the drain electrode DE.

In an embodiment, in the exposure process for removing the second interlayer insulating layer IL2, light having a beam width of about 1.5μm to about 2μm may be used. For example, since the light used in the exposure process satisfies this range, the first diameter DM1 of the first hole HL1 may be about 1.5μm to about 2μm.

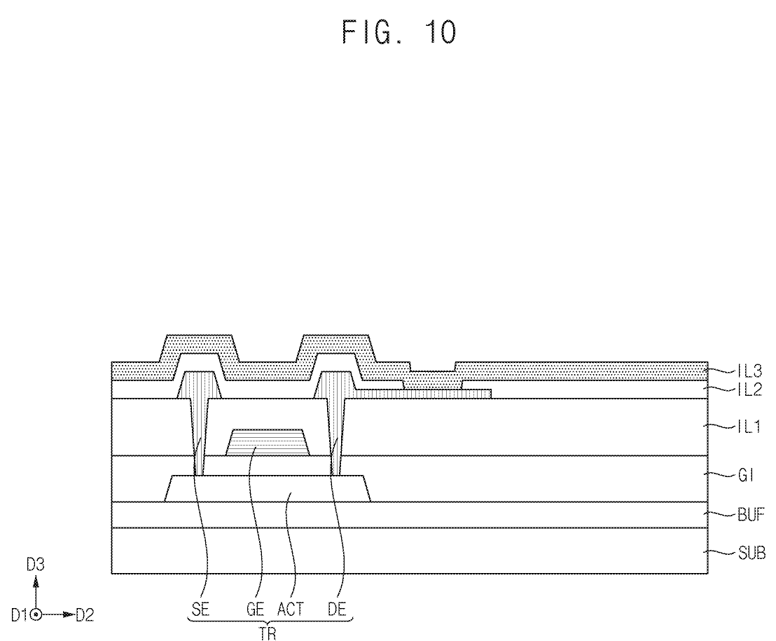

However, when using light with a beam width of about 1.5μm to about 2μm, the first diameter DM1 of the first hole HL1, which exposes an upper surface of the drain electrode DE, may be formed according to the beam width. To manufacture a high-integration display device DD, it is necessary to reduce a size of the first diameter DM1 of the first hole HL1. However, without using light with a beam width less than about 1.5μm, it is impossible to form the first diameter DM1 of the first hole HL1 to be less than about 1.5μm in the second interlayer insulating layer IL2. To address this issue, a method of forming the third interlayer insulating layer IL3 on the second interlayer insulating layer IL2 to reduce a hole diameter HL may be provided. A method for reducing the hole diameter HL will be described later with reference to FIGS. 10, 11, and 12.

Referring further to FIGS. 9 and 10, the third interlayer insulating layer IL3 may be formed on the second interlayer insulating layer IL2. The third interlayer insulating layer IL3 may be formed along a profile (or upper surface) of the second interlayer insulating layer IL2. Therefore, the third interlayer insulating layer IL3 may be bent along the third direction D3. The third interlayer insulating layer IL3 may include bends corresponding to the first hole HL1.

For example, the third interlayer insulating layer IL3 may be disposed on the second interlayer insulating layer IL2 and may fill an interior (or inside) of the first hole HL1. For example, the third interlayer insulating layer IL3 may be formed along an inner sidewall of the first hole HL1. Accordingly, the third interlayer insulating layer IL3 may be formed in contact with (e.g., in direct contact with) an upper surface of the drain electrode DE.

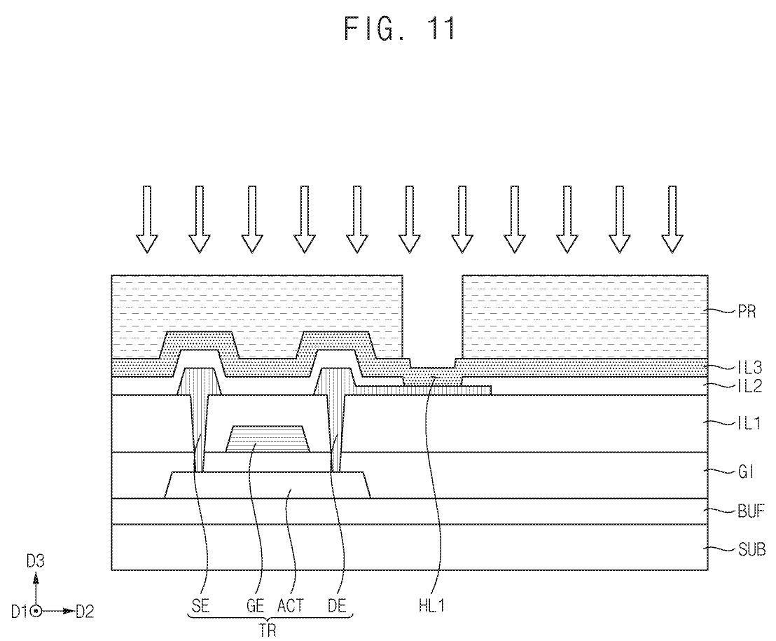

Referring further to FIG. 11, a photoresist PR may be applied to the third interlayer insulating layer IL3. The photoresist PR may be applied while being spaced apart from the first hole HL1 in a plan view. For example, the photoresist PR may not cover the first hole HL1. The photoresist PR may be either a positive photoresist or a negative photoresist.

After the photoresist PR is applied to the third interlayer insulating layer IL3, an etching process may be performed on the third interlayer insulating layer IL3. A portion of the third interlayer insulating layer IL3 where the photoresist PR is applied may not be affected by plasma or the like during the etching process. For example, in case that the etching process is performed, the photoresist PR may prevent the third interlayer insulating layer IL3, which overlaps the photoresist PR in a plan view, from being etched.

In an embodiment, the etching process may be an anisotropic etching process. Accordingly, the third interlayer insulating layer IL3 may be etched with greater precision than in an isotropic etching process. In another example, the etching process may be a dry etching process. However, embodiments are not limited thereto.

In FIG. 11, the photoresist PR is applied when performing the etching process on the third interlayer insulating layer IL3. However, in another example, applying the photoresist PR may be omitted. For example, an entire surface of the third interlayer insulating layer IL3 may undergo the etching process without being protected by the photoresist PR.

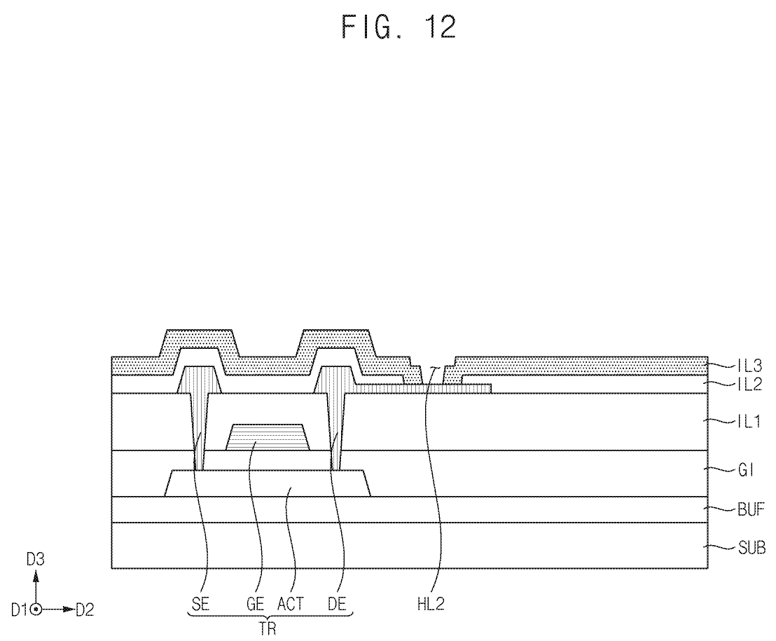

Referring further to FIGS. 4 and 12, the second hole HL2 may be formed in the third interlayer insulating layer IL3 through the etching process. The second hole HL2 may expose at least a portion of an upper surface of the drain electrode DE of the transistor TR. The second hole HL2 may be formed along an inner surface of the first hole HL1 by an amount corresponding to the second thickness L2 of the third interlayer insulating layer IL3. Accordingly, the second diameter DM2 of the second hole HL2, which is formed by the third interlayer insulating layer IL3, may be less than the first diameter DM1 of the first hole HL1.

In an embodiment, as the second hole HL2 is formed through an anisotropic etching process, an acute angle among the angles AG formed between an inner sidewall of the second hole HL2 and an upper surface of the substrate may be about 80 degrees or more. For example, the acute angle among the angles AG formed between an inner sidewall of the second hole HL2 and an upper surface of the substrate may be about 85 degrees or more. For example, an inner sidewall of the second hole HL2 may be formed at an angle substantially perpendicular to an upper surface of the substrate SUB.

According to the manufacturing method, even when exposure equipment emitting light with a beam width of about 1.5μm to about 2.0μm is used, the diameter of the hole HL may be reduced to about 0.8μm or less. Accordingly, the second hole HL2 having the second diameter DM2 may be formed without replacing exposure equipment with one that has a smaller beam width.

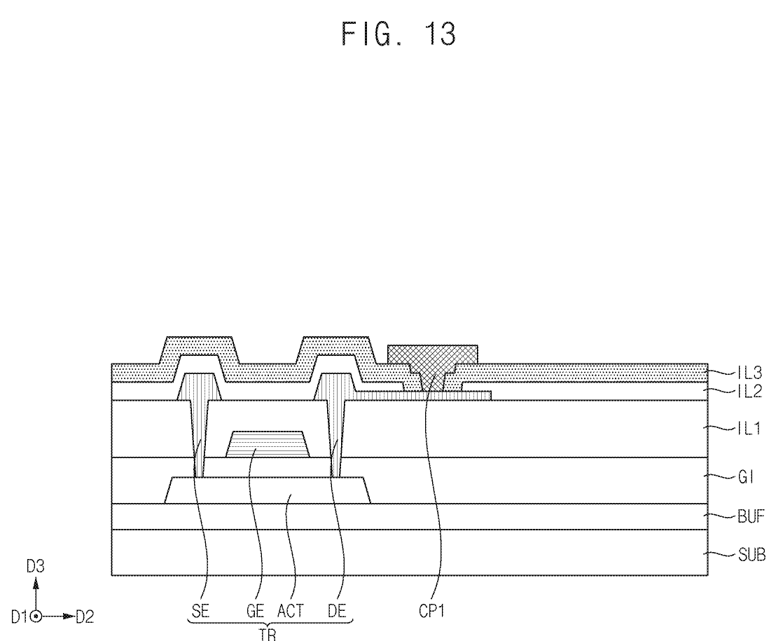

Referring further to FIG. 13, the first conductive pattern CP1 may be formed in the second hole HL2. The first conductive pattern CP1 may fill the second hole HL2 and may contact (e.g., directly contact) the drain electrode DE. The first conductive pattern CP1 may be formed to extend along the third direction D3 along the inner sidewall of the second hole HL2.

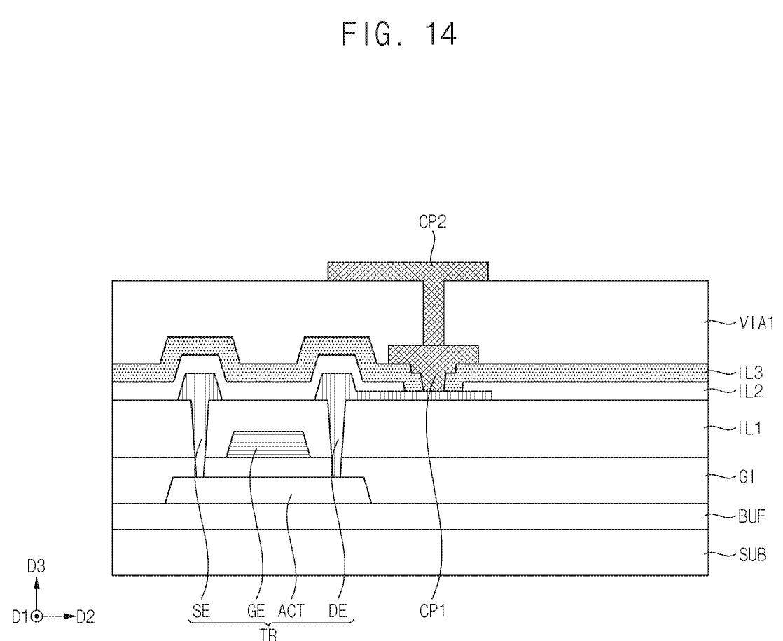

Referring further to FIG. 14, a first via layer VIA1 and a second conductive pattern CP2 may be sequentially formed on the third interlayer insulating layer IL3. For example, the first via layer VIA1 may be formed covering the third interlayer insulating layer IL3 and the first conductive pattern CP1. The second conductive pattern CP2 may be formed to penetrate the first via layer VIA1 and contact (e.g., directly contact) the first conductive pattern CP1.

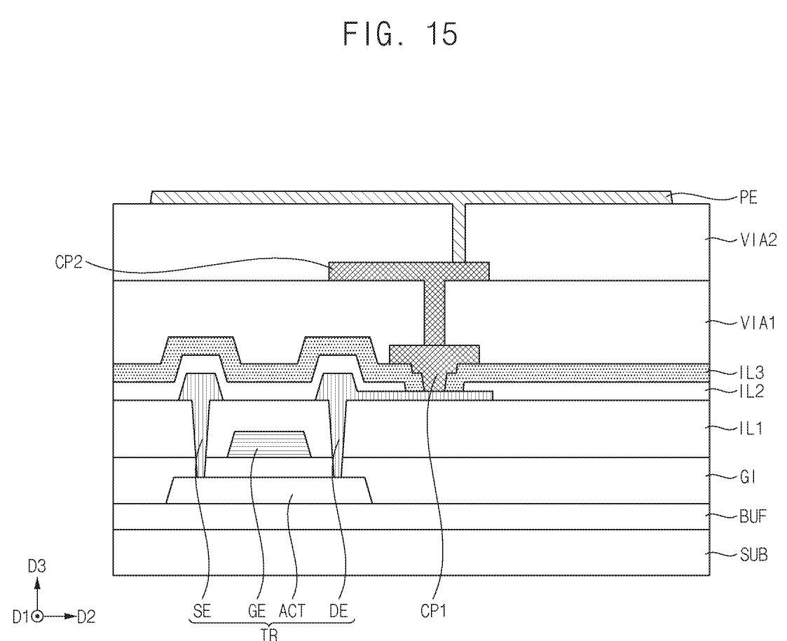

Referring further to FIGS. 3 and 15, a second via layer VIA2 and a pixel electrode PE may be sequentially formed on the first via layer VIA1. For example, the second via layer VIA2 may be formed covering the first via layer VIA1 and the second conductive pattern CP2. The pixel electrode PE may be formed to penetrate the second via layer VIA2 and contact (e.g., directly contact) the second conductive pattern CP2.

After this, the pixel defining layer PDL, the light-emitting layer EL, the common electrode CE, and the encapsulation layer ENC may be sequentially formed. Accordingly, the display panel DP of FIG. 3 may be formed.

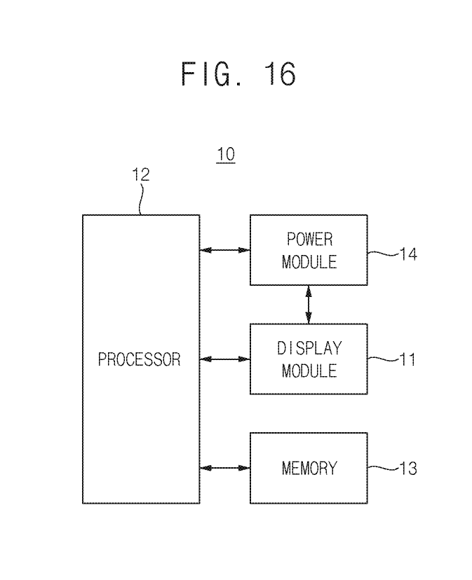

FIG. 16 is a block diagram showing an electronic device according to an embodiment.

Referring to FIGS. 1 and 16, the display device DD according to embodiments may be applied to various electronic devices 10. An electronic device 10 according to an embodiment may include the display device DD and additional modules or devices providing other functionalities.

The electronic device 10 may include a display module 11, a processor 12, a memory 13, and a power module 14.

The processor 12 may include at least one of a central processing unit CPU, an application processor AP, a graphics processing unit GPU, a communication processor CP, an image signal processor ISP, and a controller.

The memory 13 may store data and information required for the operation of the processor 12 or the display module 11. In case that the processor 12 executes an application stored in the memory 13, video data signals and/or input control signals may be transmitted to the display module 11. The display module 11 may process the received signals to output video information on the display screen.

The power module 14 may include a power adapter, a battery device, and a power conversion module for generating the power required for the operation of the electronic device 10.

At least one component of the electronic device 10 described above may be included in the display device according to the embodiments. Some individual components functionally included in a module may be integrated into the display device, while others may be provided separately from the display device. For example, the display device DD may include the display module 11, while the processor 12, the memory 13, and the power module 14 may be provided as separate devices within the electronic device 10.

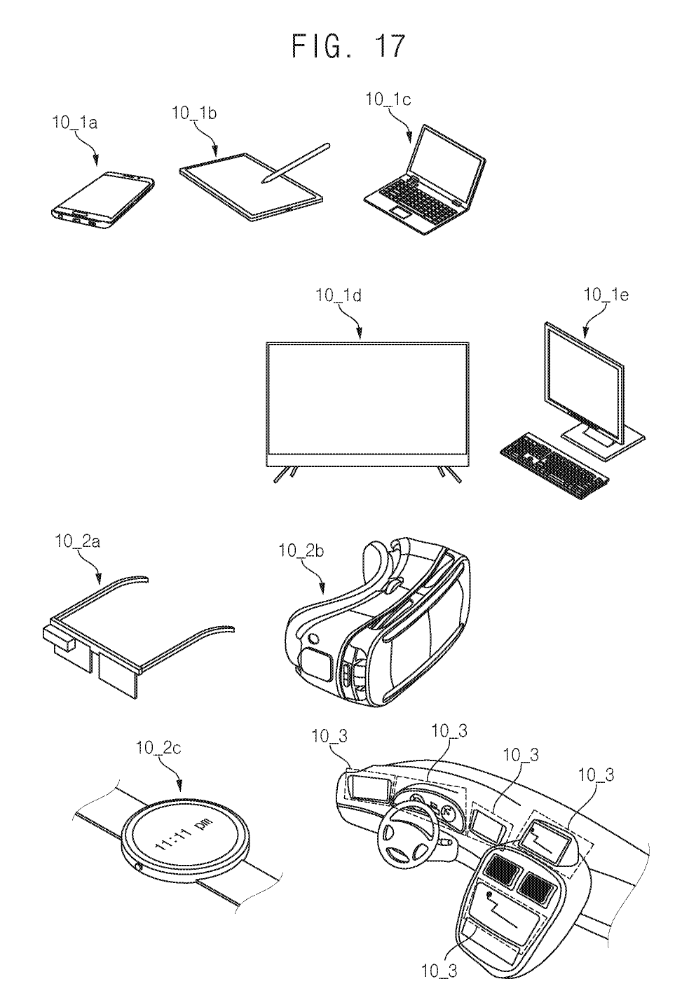

FIG. 17 is schematic diagrams showing various embodiments of the electronic device of FIG. 16.

Referring to FIGS. 16 and 17, various electronic devices 10 including the display device DD may include image-display electronic devices such as smartphones 10_1a, tablet PCs 10_1b, laptops 10_1c, TVs 10_1d, and desktop monitors 10_1e. For example, wearable electronic devices including display modules, such as smart glasses 10_2a, head-mounted displays 10_2b, and smartwatches 10_2c, and vehicle electronic devices including display modules, such as instrument clusters, center information displays (CID), and room mirror displays, may also be included.

However, these examples are illustrative, and the electronic device 10 according to the embodiments is not limited thereto. For example, the electronic device 10 may be implemented as a mobile phone, videophone, smart pad, smartwatch, tablet PC, vehicle display, computer monitor, laptop, or head-mounted display device. For example, the electronic device 10 may be a television, monitor, laptop computer, or tablet. Furthermore, the electronic device 10 may also be a vehicle.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a transistor disposed on a substrate;
a first insulating layer disposed on the transistor and including a first hole having a first diameter of about 1.5μm to about 2.0μm in a plan view;
a second insulating layer covering an upper surface of the first insulating layer and an inner surface of the first hole, and including a second hole having a second diameter of 0.8μm or less in a plan view;
a conductive pattern disposed in the second hole of the second insulating layer and electrically connected to the transistor; and
a light-emitting diode disposed on the conductive pattern.

2. The display device of claim 1, wherein a second thickness of the second insulating layer is greater than a first thickness of the first insulating layer.

3. The display device of claim 1, wherein the second thickness of the second insulating layer is in a range of about 500 nm to about 600 nm.

4. The display device of claim 1, wherein each of the first hole and the second hole has a trapezoidal shape in a cross-sectional view.

5. The display device of claim 4, wherein an acute angle between an inner surface of the second hole and an upper surface of the substrate is about 80 degrees or more.

6. The display device of claim 1, wherein each of the first insulating layer and the second insulating layer includes an inorganic material.

7. The display device of claim 1, wherein the second hole exposes an upper surface of a source/drain electrode of the transistor.

8. The display device of claim 1, wherein the second hole penetrates the first insulating layer and the second insulating layer in a thickness direction.

9. The display device of claim 1, wherein the conductive pattern extends in a thickness direction along the second hole.

10. The display device of claim 1, wherein the conductive pattern is electrically connected to a pixel electrode of the light-emitting diode.

11. A method of manufacturing a display device comprising:
forming a transistor on a substrate;
depositing a first insulating layer on the transistor;
forming a first hole including a first diameter of about 1.5μm to about 2.0μm in a plan view in the first insulating layer;
depositing a second insulating layer on an upper surface of the first insulating layer and an inner surface of the first hole, the second insulating layer defining a second hole including a second diameter of about 0.8μm or less in a plan view;
etching the second insulating layer to expose an upper surface of a source/drain electrode of the transistor;
forming a conductive pattern in the second hole; and
forming a light-emitting diode on the conductive pattern.

12. The method of claim 11, further comprising:
applying a photoresist on the second insulating layer after depositing the second insulating layer.

13. The method of claim 12, wherein in the applying of the photoresist, the photoresist is spaced apart from the first hole in a plan view.

14. The method of claim 11, wherein, in the depositing of the second insulating layer, a thickness of the second insulating layer is formed thicker than a thickness of the first insulating layer.

15. The method of claim 11, wherein, in the forming of the second hole, an acute angle between an inner surface of the second hole and an upper surface of the substrate is about 80 degrees or more.

16. The method of claim 11, wherein the etching of the second insulating layer includes an anisotropic etching process.

17. An electronic device, comprising:
a display device; and
a processor that drives the display device, and
wherein the display device includes:
a transistor disposed on a substrate;
a first insulating layer disposed on the transistor and defining a first hole including a first diameter of about 1.5μm to about 2.0μm in a plan view;
a second insulating layer covering an upper surface of the first insulating layer and an inner surface of the first hole, and defining a second hole including a second diameter of 0.8μm or less in a plan view;
a conductive pattern disposed in the second hole of the second insulating layer and electrically connected to the transistor; and
a light-emitting diode disposed on the conductive pattern.

18. The electronic device of claim 17, wherein a first thickness of the first insulating layer is less than a second thickness of the second insulating layer.

19. The electronic device of claim 17, wherein the second hole has a trapezoidal shape in a cross-sectional view, and
an acute angle between an inner surface of the second hole and an upper surface of the substrate is about 80 degrees or more.

20. The electronic device of claim 17, wherein the second hole exposes an upper surface of a source/drain electrode of the transistor.
